(19) United States
(12) Patent Application Publication
(10) Pub. No.: US 2005/0037143 A1
(43) Pub. Date: Feb. 17, 2005

(54) Imprint lithography with improved monitoring and control and apparatus therefor

(76) Inventors: Stephen Y. Chou, Princeton, NJ (US); Zhaoning Yu, Levittown, PA (US)

Correspondence Address: DOCKET ADMINISTRATOR;LOWENSTEIN SANDLER PC, 65 LIVINGSTON AVENUE, ROSELAND, NJ, 07068, US

(21) Appl. No.: 10/863,975

(22) Filed: Jun. 9, 2004

Related U.S. Application Data
(63) Continuation-in-part of application No. 10/637,838, filed on Aug. 8, 2003.
Application No. 10/637,838 is a continuation-in-part of application No. 10/140,140, filed on May 7, 2002.
Application No. 10/140,140 is a division of application No. 09/618,174, filed on Jul. 18, 2000, now Pat. No. 6,482,742.
Application No. 10/637,838 is a continuation-in-part of application No. 10/046,594, filed on Oct. 29, 2001.
(60) Provisional application No. 60/477,161, filed on Jun. 9, 2003.

(51) Int. Cl. B31F 1/07; B44B 5/00; B41F 19/02; C23C 16/00

(52) U.S. Cl. 427/248.1

(57) ABSTRACT

In accordance with the invention, at least one parameter of a method for imprinting a mold pattern on the surface of a workpiece is monitored or measured. The monitoring or measuring is accomplished by a) providing a mold having a molding surface configured to imprint at least a test pattern for measurement; b) imprinting the test pattern on the moldable surface by pressing the molding surface into the moldable surface; c) illuminating the test pattern with radiation during at least a portion of the imprinting, and monitoring or measuring at least one component of the radiation scattered, reflected or transmitted from the test pattern to monitor or measure the at least one parameter of the imprinting. The imprinting step typically comprises disposing the mold near the workpiece with the molding surface adjacent the moldable surface, pressing the molding surface into the moldable surface and removing the molding surface from the moldable surface to leave the imprinted pattern. In many cases, the pressing can be facilitated by heating the moldable surface, and retention of the imprinted pattern can be assisted by cooling or curing the deformed surface material. Moreover the process can be controlled by detecting the component of the radiation, generating a feedback control signal from the detected signal, and using the feedback control signal to control the imprint process in real time. The invention also includes advantageous apparatus for the above methods of monitoring, measuring and controlling imprint lithography.

### CROSS REFERENCE TO RELATED APPLICATIONS

This application claims the benefit of U.S. Provisional Application Ser. No. 60/477,161 filed by Stephen Y. Chou and Zhaoning Yu on Jun. 9, 2003 and entitled “Methods and Apparatus for Monitoring and Controlling of Imprinting Processes and Materials”. The '161 Provisional Application is incorporated herein by reference.

The present application is a continuation-in-part of U.S. patent application Ser. No. 10/637,838 filed by Stephen Y. Chou, Hua Tan and Wei Zhang on Aug. 8, 2003 and entitled “Lithographic Apparatus For Fluid Pressure Imprint Lithography.” The '838 application is incorporated herein by reference.

The '838 application is continuation-in-part of U.S. patent application Ser. No. 10/140,140 filed May 7, 2002 and entitled “Fluid Pressure Imprint Lithography”. Ser. No. 10/140,140, in turn, is a divisional of U.S. patent application Ser. No. 09/618,174 filed Jul. 18, 2000 (now U.S. Pat. No. 6,482,742 issued Nov. 19, 2002). The foregoing '140 application, '174 application and '742 patent are each incorporated herein by reference.

The '838 application is also a continuation-in-part of U.S. patent application Ser. No. 10/046,594 filed on Oct. 29, 2001, which claims priority to U.S. patent application Ser. No. 09/107,006 filed Jun. 30, 1998 (now U.S. Pat. No. 6,309,580 issued Oct. 30, 2001) and which, in turn, claims priority to U.S. patent application Ser. No. 08/558,809 filed on Nov. 15, 1995 (now U.S. Pat. No. 5,772,905 issued Jun. 30, 1998). The foregoing '594 application, the '006 application and the '809 application are each incorporated herein by reference.

The present application is also a continuation-in-part of United States Published patent application Ser. No. 2004/0046288 filed by Stephen Y. Chou on Mar. 11, 2004 entitled “Laser Assisted Direct Imprint Lithography”, which published application is incorporated herein by reference.

The published application Ser. No. 2004/0046288 claims the benefit of Provisional Application No. 60/364,653 filed Mar. 15, 2002. The published application is a continuation-in-part of application Ser. No. 10/140,140, filed on May 7, 2002, which is a division of application Ser. No. 09/618,174, filed on Jul. 18, 2000, now Pat. No. 6,482,742. It is also a continuation-in-part of application Ser. No. 10/244,276, filed on Sep. 16, 2002, which is a continuation of application Ser. No. 10/046,594 filed on Oct. 29, 2001. The foregoing '653 application, '140 application, '174 application, '742 patent, '276 application and '594 application are all incorporated herein by reference.

### FILED OF THE INVENTION

This invention relates to imprint lithography for imprinting a mold pattern on the surface of a workpiece having a moldable surface by pressing a molding surface into the moldable surface. More specifically it relates to a method and apparatus for monitoring and controlling such imprint lithography that is especially useful for imprinting patterns having microscale or nanoscale features.

### BACKGROUND OF THE INVENTION

Methods of patterning small features onto substrates are of great importance in the fabrication of many electronic, magnetic, mechanical, and optical devices as well as devices for biological and chemical analysis. Such methods are used, for example, to define the features and configurations of microcircuits and the structure and operating features of planar optical waveguides and associated optical devices.

Optical lithography is the conventional method of patterning such features. A thin layer of photoresist is applied to the substrate surface and selected portions of the resist are exposed to a pattern of light. The resist is then developed to reveal a desired pattern of exposed substrate for further processing such as etching. A difficulty with this process is that resolution is limited by the wavelength of the light, scattering in the resist and substrate, and the thickness and properties of the resist. As a consequence optical lithography becomes increasingly difficult as desired feature size becomes smaller. Moreover applying, developing and removing resists are relatively slow steps, limiting the speed of throughput.

Imprint lithography, based on a fundamentally different principle, offers high resolution, high throughput, low cost and the potential of large area coverage. In imprint lithography, a mold with small features is pressed onto a workpiece having a moldable surface (such as a resist-coated substrate). The mold features deform the shape of the moldable resist film, deforming the shape of the film according to the features of the mold and forming a relief pattern in the film surface. After the mold is removed, the patterned thin film can be processed to remove the reduced thickness portions. This removal exposes the underlying substrate for further processing. Using a mechanical press to effect the pressing step, such imprinting can imprint sub-25 nanometer features with a high degree of uniformity over areas on the order of 12 square inches. For further details see U.S. Pat. No. 5,772,905 issued to Stephen Y. Chou on Jun. 30, 1998 which is incorporated herein by reference.

Even higher resolution, larger area imprint lithography can be accomplished if the tolerance problems presented by high precision mechanical presses can be overcome. This can be achieved by using direct fluid pressure to press together the mold surface and the moldable surface. Because fluid pressure is isostatic, no significant unbalanced lateral forces are applied in the pressing step. Further details are set forth in U.S. Pat. No. 6,482,742 issued to Stephen Y. Chou on Nov. 19, 2002 and entitled “Fluid Pressure Imprint Lithography”, which is incorporated herein by reference. Advantageous apparatus for fluid pressure imprint lithography is described in U.S. patent application Ser. No. 10/637,838 filed by Stephen Chou et al. on Aug. 8, 2003 which is incorporated herein by reference.

It is also possible to achieve imprint lithography by pressing a mold directly into the surface of a substrate, thus providing a workpiece where the moldable surface is the surface of a substrate. For example, the moldable surface can be a material for a part of a device, such as an organic light emitting material, an organic conducting material, insulator, or a low-K dielectric material. As another example, a silicon workpiece can be directly imprinted with a nanoscale pattern. The molding surface is disposed adjacent the silicon surface to be molded. The silicon surface is irradiated with laser radiation to soften or liquefy the silicon, and the molding surface is pressed into the softened or liquefied surface. For further details, see United States Published patent application Ser. No. 2004/0046288 filed by Stephen Chou on Mar. 17, 2003 and entitled “Laser Assisted Direct Imprint lithography, which is incorporated herein by reference.

Because of their potential for high speed, high resolution fabrication of numerous important products, it is desirable to monitor and study the imprint lithography process, to optimize the process parameters, to optimize material components, and to control the process in real time. This invention presents an advantageous method to achieve such monitoring, optimization and control.

### SUMMARY OF THE INVENTION

In accordance with the invention, at least one parameter of a method for imprinting a mold pattern on the surface of a workpiece is monitored or measured. The monitoring or measuring is accomplished by a) providing a mold having a molding surface configured to imprint at least a test pattern for measurement; b) imprinting the test pattern on the moldable surface by pressing the molding surface into the moldable surface; c) illuminating the test pattern with radiation during at least a portion of the imprinting, and monitoring or measuring at least one component of the radiation scattered, reflected or transmitted from the test pattern to monitor or measure the at least one parameter of the imprinting. The imprinting step typically comprises disposing the mold near the workpiece with the molding surface adjacent the moldable surface, pressing the molding surface into the moldable surface and removing the molding surface from the moldable surface to leave the imprinted pattern. In many cases, the pressing can be facilitated by heating the moldable surface, and retention of the imprinted pattern can be assisted by cooling or curing the deformed surface material. Moreover the process can be controlled by detecting the component of the radiation, generating a feedback control signal from the detected signal, and using the feedback control signal to control the imprint process in real time. The invention also includes advantageous apparatus for the above methods of monitoring, measuring and controlling imprint lithography.

### BRIEF DESCRIPTION OF THE DRAWINGS

The accompanying drawings, which are incorporated into and form part of the specification, illustrate one or more embodiments of the present invention and, together with the description, serve to explain the principles of the invention. The drawings are only for the purpose of illustrating one or more preferred embodiments of the invention and are not to be construed as limiting the invention.

In the drawings:

FIGS. 1A through 1E schematically illustrate different phases of the imprinting processes and materials to be monitored by the metrology method described in the present invention.

FIG. 2 schematically shows measuring apparatus in accordance with one embodiment of the invention;

FIG. 3 illustrates a structure measured in accordance with an illustrative embodiment of the invention.

FIG. 4 is a scanning electron micrograph of an exemplary test pattern on the mold used in an illustrative embodiment of the invention.

FIG. 5 depicts a schematic of the experimental set-up in accordance with one illustrative embodiment of the present invention.

FIG. 6 shows measurement data obtained in the experiment illustrated in FIG. 5.

FIG. 7 is a schematic block diagram of a metrology tool in accordance with an illustrative embodiment of the present invention.

FIG. 8 is a schematic block diagram of a processing system in accordance with an illustrative embodiment of the present invention.

FIG. 9 is a graphical illustration showing measurement data obtained using the set up of FIG. 5. It illustrates the effect of processing temperature on the speed of mold penetration into resist.

FIG. 10 graphs measurement data obtained using the set up of FIG. 5. It illustrates the effect of processing pressure on the speed of mold penetration into resist.

FIG. 11 graphs measurement data obtained using the set up of FIG. 5. It illustrates the effect of pre-imprint resist baking conditions on the speed of mold penetration into resist.

FIG. 12 graphs measurement data obtained using the set up of FIG. 5. It illustrates the effect of different initial resist film thicknesses on the speed of mold penetration into resist.

FIG. 13A shows the effects (simulated) of different resist refractive index on the measurement using the set up of FIG. 5. The data was calculated using the scalar diffraction theory.

FIG. 13B shows measurement data obtained using the embodiment illustrated in FIG. 5. It shows the effect of resist refractive index on the measurement.

FIG. 14 illustrates measurement data obtained using the set up of FIG. 5. It illustrates the effects of the difference in mold features (line-width in this case) on the speed of mold penetration into resist (with different initial film thickness).

FIG. 15 shows measurement data obtained using the set up of FIG. 5. It illustrates the application of this invention in imprint process control; and

FIG. 16 is a schematic block diagram showing the steps involved in imprint lithography monitored or controlled in accordance with the invention.

### DETAILED DESCRIPTION OF THE INVENTION

The present invention is related to methods of monitoring and/or controlling the processes and materials of imprint lithography. By measuring and analyzing radiation (such as light, electron beam, or ion beam) scattered from a set of microscopic test features that are related to imprinting, imprint parameters and material properties can be measured or detected either in-situ or ex-situ, and a feedback or control signal can be generated to control the imprint process and its outcome. The invention also addresses methods and apparatus for in-situ and ex-situ monitoring the imprinting processes and materials.

These methods include:
1) Providing a mold having at least one set of test surface relief features, which may comprise a grating, a two-dimensional array, a structure with irregular or arbitrarily-defined shapes, or a three-dimensional structure;
2) Illuminating the test surface relief pattern with radiation (monochromatic or wide-band in wavelength spectrum) during the process of imprinting, which typically includes bringing the mold into proximity with the workpiece to be patterned, pressing the mold into a thin film coating on the workpiece surface, changing the thin film from a viscous to a non-viscous state (or vice versa), and separating the mold from the resist. In some cases there may be pre-existing patterns on the workpiece or substrate to be registered with a new pattern to be printed. In such cases, the pattern on the mold is aligned with the pre-existing pattern before the pressing step. The radiation can be light (visible, x-ray, ultraviolet or infrared), electron beam, or ion beam. For simplicity, the term light is used in all descriptions of the invention, but with understanding that it includes the other forms of radiation;
3) Measuring light scattered from or (in case that both the mold and substrate are relatively transparent to the radiation) transmitted through the illuminated test structure and the moldable material;
4) Extracting from the measurement information on parameters of the imprinting processes and materials. The extraction can be either in real time (in-situ) or off line and (ex-situ).
5) The extracted information can be used to generate a signal for the purpose of controlling the imprinting processes and materials in an in-situ fashion.
6) And/or the extracted information can be used to study the effects of different parameters and materials on the imprinting process.

Apparatus based on this method includes:
1) A stand-alone metrology tool based to extract information on imprinting processes and materials.
2) A processing system including an imprinting tool, a metrology tool, and a process and materials controller. The imprinting tool is adapted to perform imprint lithography in accordance with an operating recipe. The metrology tool is adapted to illuminate the mold and substrate with radiation (typically light) and to measure the scattered or transmitted radiation for extracting information on the imprinting processes and materials. The imprint process and materials controller generates signal based on data obtained from the metrology tool to control the imprinting processes and materials by adjusting one or more operating parameters in real-time.

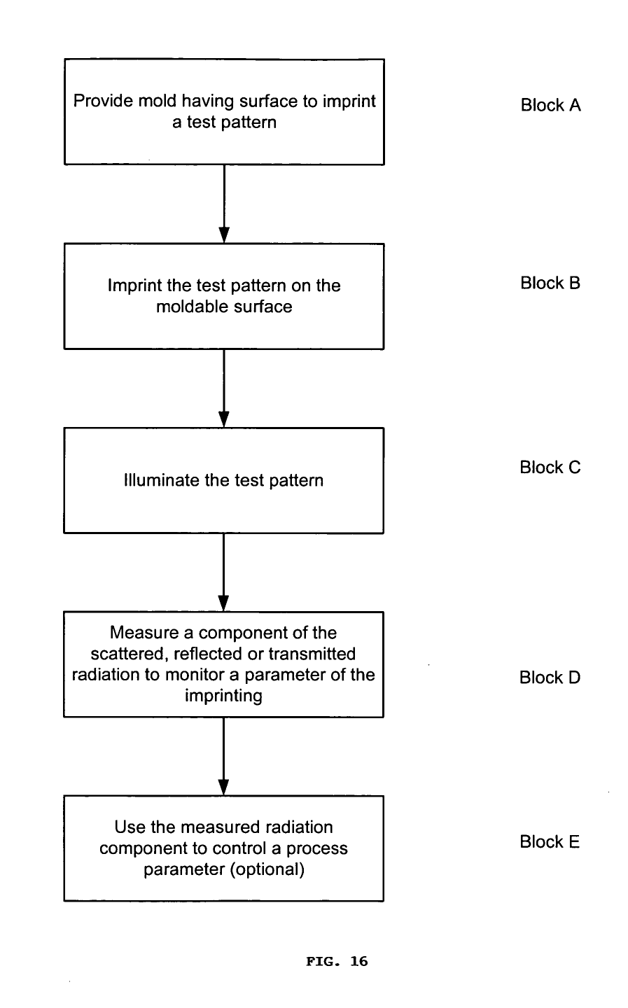

Referring to the drawings, FIG. 16 is a block diagram schematically illustrating the steps involved in monitoring or measuring and optionally controlling imprint lithography on a workpiece having a moldable surface. The first step shown in Block A is to provide a mold having a molding surface to imprint a test pattern for measurement.

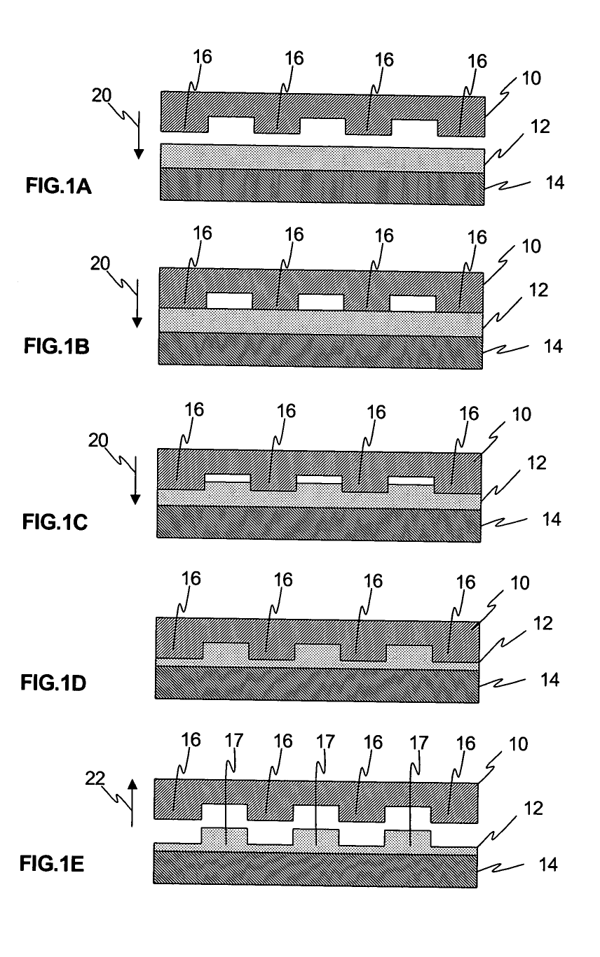

FIG. 1A shows a mold 10 with a test pattern comprising a plurality of projecting features 16 having a desired shape in proximity with a workpiece having a moldable surface. The workpiece comprises a substrate 14 carrying a thin moldable film layer 12. Arrow 20 shows the direction in which the mold moves relative to the substrate.

The next step (Block B of FIG. 16) is to imprint the moldable surface. This typically comprises disposing the mold near the workpiece with the molding surface adjacent the moldable surface, pressing the molding surface into the moldable surface and removing the molding surface from the moldable surface with the imprinted pattern left on the moldable surface. The pressing can be effected by a high precision mechanical press as described in the aforementioned U.S. Pat. No. 5,772,905, by fluid pressure as described in U.S. Pat. No. 6,482,742, or by using electrostatic or magnetic force: Heating of the moldable surface may be used to facilitate the pressing step and cooling can be used to facilitate retention of the imprinted pattern in the moldable surface. The moldable thin film can be a photocurable material which is in a liquid or a deformable state before photocuring. The moldable film 12 can be omitted if the substrate material provides a surface that is moldable or can be made moldable as exemplified by laser assisted softening of a silicon surface. See the aforementioned U.S. Published application No. 2004/0046288. The moldable surface can be a moldable film or a moldable bulk material that is part of a device. Examples of such moldable materials include semiconductors, insulators, metals, inorganic materials, organic materials, and light-emitting materials.

FIG. 1B shows the mold 10 brought into contact with the surface of the thin moldable film layer 12 carried by the substrate 14. The thin moldable film layer 12 may comprise thermoplastic composites, curable composites or composites or other moldable materials. The thin moldable film layer 12 advantageously is able to pass from a viscous state to a non-viscous state or vice versa by physical change or chemical reaction upon a change in conditions such as temperature, polymerization, curing or irradiation. Advantageously, the thin moldable film layer 12 is in a viscous state before or after it is brought into contact with mold 10.

FIGS. 1C and 1D show the features 16 on mold 10 pressed into the thin moldable film layer 12. After the features 16 have been pressed a desired depth into the thin moldable film layer 12 (FIG. 1D), after the imprinting the thin film is permitted or induced to change into a non-viscous state as by cooling or curing, at the non-viscous state the mold is removed.

FIG. 1E illustrates the mold 10 released from the thin moldable film layer 12. The mold moves away in the direction indicated by arrow 22, leaving imprinted features 17 in the thin film 12. The test features 17 generally conform to the shape of recessed features on the mold.

Referring back to FIG. 16, the third step, shown in Block C, which occurs during some portion of the imprinting process and typically during the pressing step, is illuminating at least a portion of the test pattern with radiation (typically light). Illumination can be facilitated by using a relative transparent mold and/or a relative transparent substrate, e.g. fused quartz. Typically the imprinted test features form a test grating pattern in the resist. Upon illumination with light, the grating scatters, reflects or transmits light in ways that can be analyzed to provide information concerning the imprinting process. Upon analysis, the method provides metrology for measuring and studying imprint lithography. Thus in the step of block D, at least one component of the scattered or transmitted radiation is used for monitoring, measuring or studying at least one parameter of the lithographic imprinting.

The next step shown in Block E, advances from measuring and studying to control of imprint lithography either real time or off-line. Here scattered, reflected or transmitted radiation is measured or analyzed to generate a feedback signal to control the imprinting. At least one component of the scattered or transmitted radiation is measured and analyzed to control at least one parameter of the imprinting. Advantageously one or more components are used to generate feedback to control a plurality of imprint parameters.

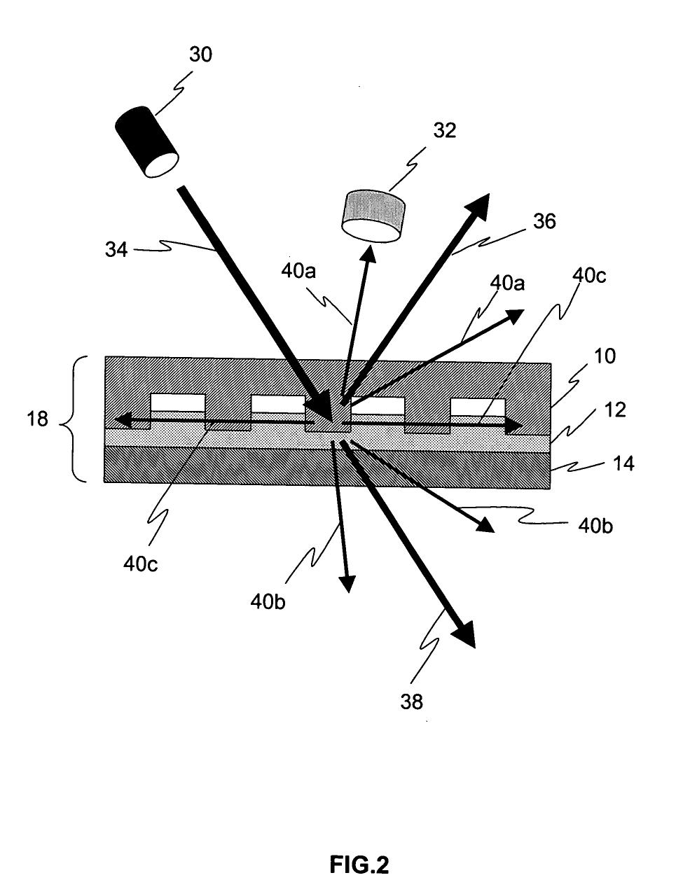

FIG. 2 is a schematic illustrating the metrology that measures imprint parameters and material properties. A beam of radiation (e.g. light, electron, or ion beam) 34 from a radiation source 30 is used as a probe to illuminate at least a portion of the assembly 18, consisting of a mold 10, a thin moldable film layer 12 (which can also have a multi-layer resist structure), and a substrate 14 (which can be either a flat substrate or a substrate carrying patterns or structures). For simplicity, the term “light source” or “light” are used in all descriptions, but with the understanding that it includes sources of other forms of radiation.

The light to be detected and analyzed typically includes a reflected component (the so-called ‘specular’ component) 36, a transmitted component 38, and scattered components 40 (40a, 40b and 40c). For simplicity of discussion, the term “scattered” light is meant to encompass all of these components, unless otherwise stated. The detector 32 takes optical measurements, such as intensity, phase, or polarization, of one or more scattered components.

The light source 30 may use essentially monochromatic light, white light (wide-band), or some other combinations of wavelengths. It may use light of any polarization or any combination of polarized and nonpolarized light. It may use illumination at any angle of incidence. Although FIG. 2 shows the assembly 18 being illuminated by a light beam 34 coming from the side of the mold 10, the assembly can as well be illuminated from the side of the substrate 14. The light source can be a focused and directional beam or non-focused broad beam. The useful wavelength of light ranges from 1 nm to 100 μm. The useful electron beam wavelength ranges from 0.001 nm to 10 μm. And the useful ion beam wavelength ranges from 0.00001 nm to 10 μm. The dimensions of the probed features (which can be on the mold, on the substrate, or in the resist) are from typically 0.1 nm to 500 μm in width, and 0.1 nm to 100 μm in depth.

The scattered light profile (i.e. its angular distribution, intensity, phase, and polarization) depends on: 1) the incident light 34 profile (i.e. its angle of incidence, intensity, wavelength, phase, and polarization); 2) the materials and compositions of the mold 10, thin moldable film layer 12, and substrate 14; 3) characteristics (e.g. shape, height, intrusion depth of mold features into the resist, arrangement, and relative orientation) of patterns on the mold 10 and patterns in the thin moldable film layer 12 that are being illuminated.

By measuring and analyzing the scattered light profile, information on parameters of the imprinting process and materials can be extracted. Those parameters include, but are not limited to: the degree of intrusion of mold features into the resist, the speed at which the mold is moving relative to the substrate, the gap between the mold and the resist film, the gap between the mold and substrate, the conditions of the resist film including viscosity and degree of polymerization, the parallelism between the mold and the substrate, the relative orientation of the mold and the substrate, the overlay accuracy between the mold features and the features on the substrate coming from previous processing, and changes in the shape of the mold, substrates and resist. The conditions of resists that can be measured include stresses, deformation, composition, viscosity, flowing speed, flowing direction, phase transitions, degree of polymerization, degree of cross-linking, change of hardness, and change in optical properties. The above measurements can be done in real-time and in-situ or off-line and ex-situ. The information extracted from the above measurements can be used to analyze and control the imprint tools, imprint processes, and imprint materials either in-situ or ex-situ.

The information obtained in-situ from the characterization can be used to control, in real time, various imprint parameter such as the relative positions (x, y, z, theta, yank and yaw—all six possible degrees of freedom) between the mold and the substrate, the imprint speed, imprint pressures, imprint temperatures, the change of the mold, and the local and global alignments between the substrate and the mold.

These metrology tools in the present invention can be tailored to suit specific implementations. For example, the test features on the mold can be designed to enhance the scattered light intensity in a specific diffraction order to optimize the measurement of a specific parameter such as the degree of intrusion of mold features into the resist.

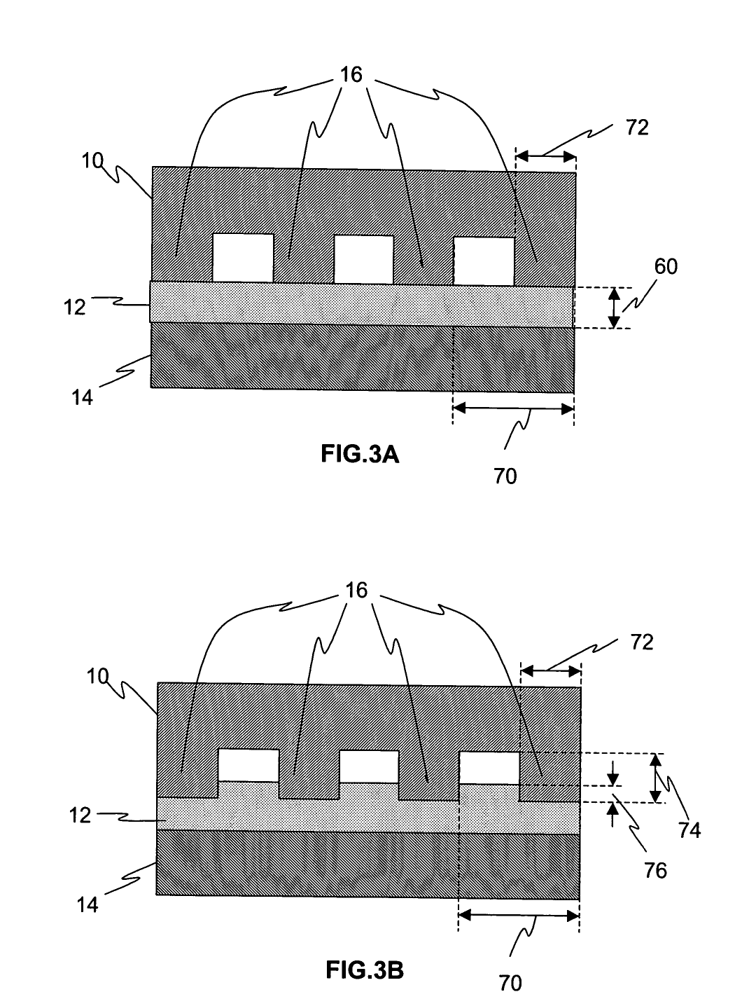

FIGS. 3 through 6 illustrate an embodiment for detecting the degree of mold intrusion into the resist.

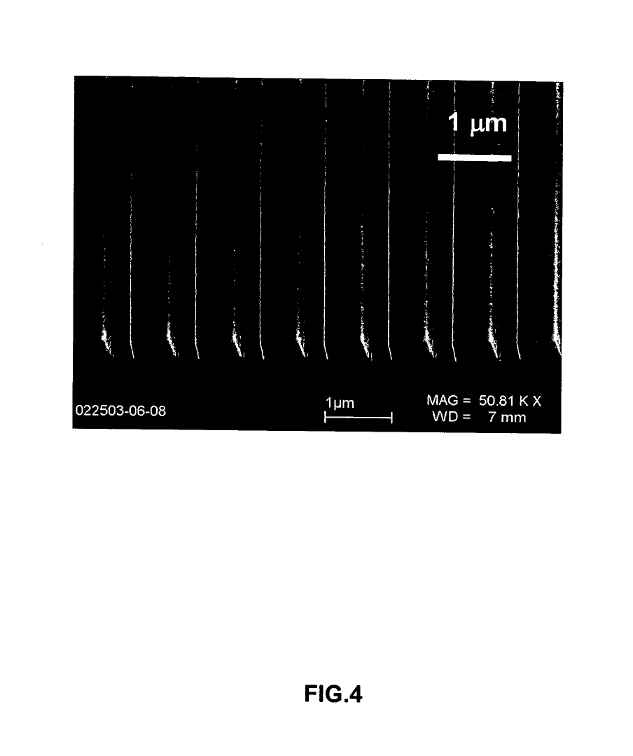

FIG. 3 shows a specific example of an assembly to be illuminated by probing light 34. The mold 10 is a transparent mold made of a 0.5 mm thick fused-silica substrate with a polished backside. The test features are a set of grating elements with a period of 1 μm and a line-width of 650 nm. The depth of the test pattern is around 400 nm. thin moldable film layer 12 is a thermoplastic polymer with an initial film thickness 60 and a refractive index nᵣ=1.46, and the resist can be turned into a viscous state at elevated temperatures. The substrate 14 is silicon. FIG. 4 is a scanning electron micrograph of the pattern on the mold to imprint a test grating.

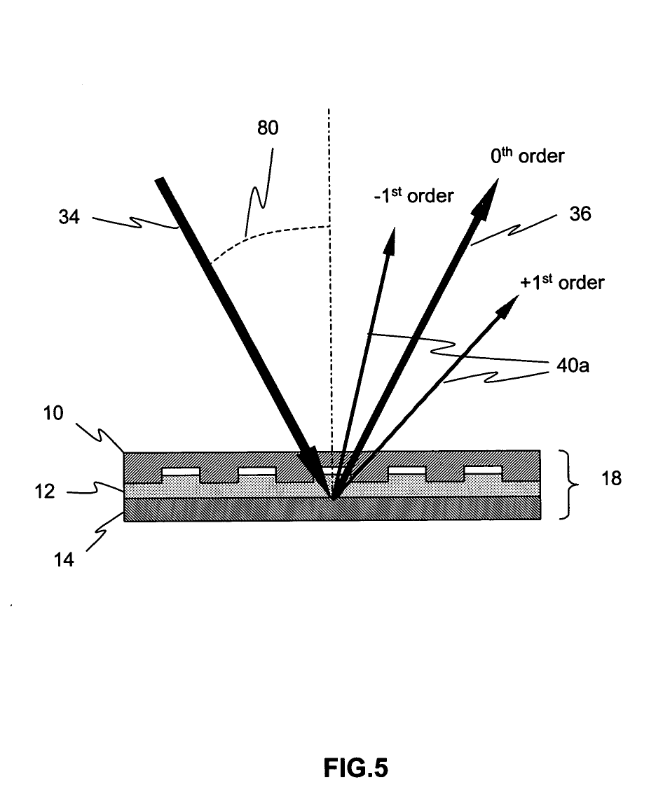

FIG. 5 shows a schematic of the measurement set-up. A He—Ne laser 30 is used as the light source. The probing beam 34 has a wavelength of 632.8 nm and is polarized parallel to the plane of incidence (the probing beam can alternatively be polarized perpendicular to the plane of incidence, or it can be in other states of polarization without significantly changing the results in this embodiment). An angle of incidence 80 of 30° is used in this set-up. Other incident angles can be used.

In operation, the mold 10 is brought into contact with the thin moldable film layer 12 carried by the substrate 14 at room temperature. The assembly 18 is illuminated by the probing light beam coming from the side of the mold, with the grating aligned parallel to the plane of incidence. The grating can alternatively be aligned in other directions relative to the plane of incidence.

An external fluid pressure is applied to press the mold against the substrate during the whole process. The assembly 18 is heated so that the elevated temperature can turn the resist to its viscous state.

Because the test pattern is an array of periodic features (a diffraction grating), illumination gives rise to a number of “orders” of light beams scattered from the grating. In this set-up, there are typically three diffraction orders comprising the zeroth order 30 (known as the ‘specular’ order) and two 1^{st} order beams 40a.

The relative intensities of different orders depends strongly on the degree of intrusion of the test grating on the mold into the resist. When the mold features are pressed into the resist film so that the trenches between the grating lines are filled with a resist material of approximately matching refractive index, the intensity of the 1^{st} diffraction orders will decrease.

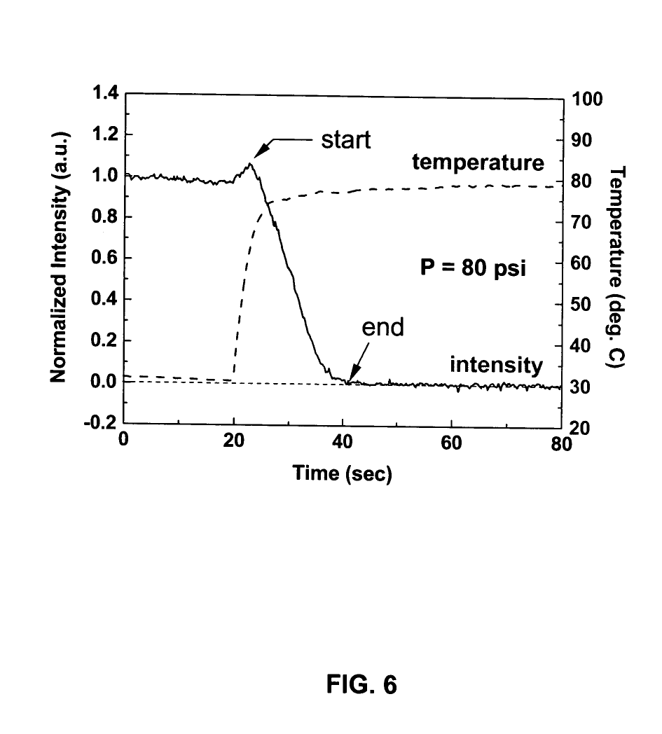

In this embodiment, one photo-detector 32 is used to measure the intensity of a 1^{st} order beam. The time-resolved data obtained from such measurement is shown in the graph of FIG. 6. The graph demonstrates the sensitivity of this metrology and its ability to resolve different phases of the imprint process.

The relative high intensity of the 1^{st} order diffraction at the beginning of this process indicates that although the mold is in contact with the resist film under an external pressure (a constant pressure of 80 psi is applied during the whole process), the mold features are not pressed into the resist during this initial stage. The subsequent decrease in the diffracted intensity indicates that as the resist is softened by heating, the mold presses into the resist. The near zero 1^{st} order diffraction intensity at the end of the process indicates that the mold features are completely pressed into the resist, and the trenches between the grating lines are filled with the index matching material.

This example shows that the metrology of the present invention can be used in an in-situ or ex-situ fashion for the monitoring and studying of the imprint process. Key information on the imprinting (such as the degree of intrusion of mold into the resist, start and end-point detection, and speed of the process) can be drawn from the measurements.

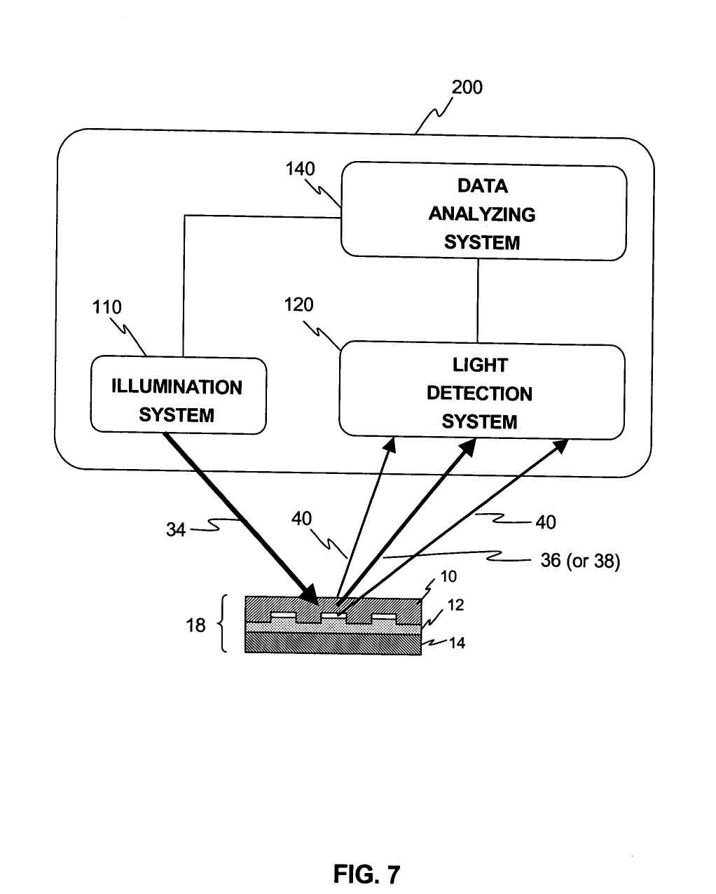

FIG. 7 is a simplified block diagram of a stand-alone apparatus 200 (metrology tool) for monitoring the imprint processes and materials in accordance with the invention. The metrology tool 200 includes: 1) an illumination system 110 for the generation of one or multiple probing light beams 34; 2) optical hardware 120 for detecting and measuring scattered light; and 3) a data analyzing system 140 for processing data collected by the optical hardware and outputting the results in a desirable format.

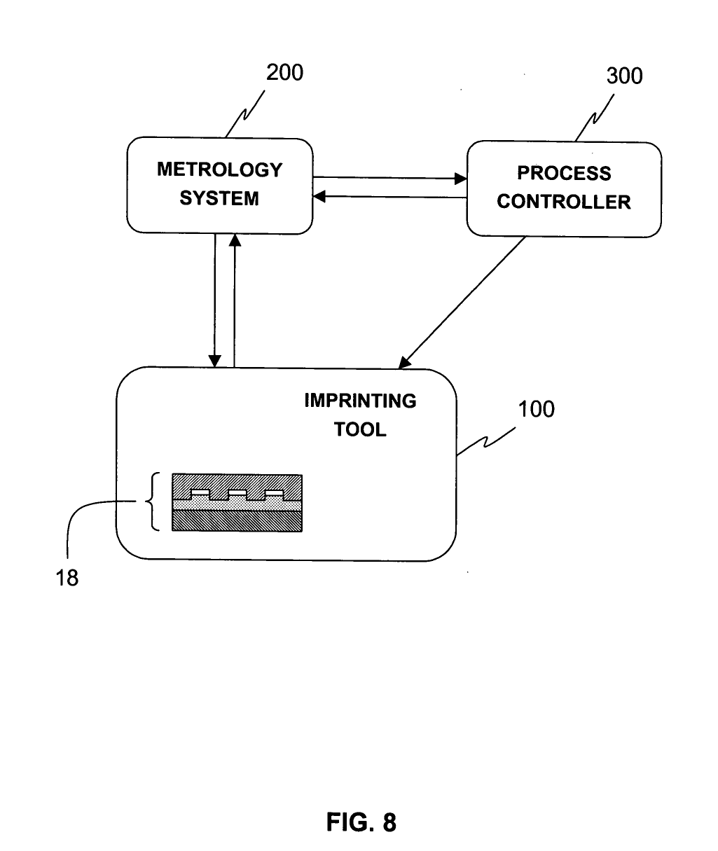

FIG. 8 is a simplified block diagram of a processing system for performing imprint lithography in accordance with the present invention. The processing system includes: 1) an imprinting tool 100 which performs imprint lithography. Parameters of the tool's processing recipes (e.g. mold position in all dimensions, substrate position in all dimensions, the overlay alignment between the mold and the substrate, imprint pressure, imprint temperature, and imprint duration) can be changed and controlled by external input in a pre-set or real-time fashion; 2) a metrology tool 200 as depicted in FIG. 7; and 3) a process controller 300 capable of generating real-time control signal by receiving and analyzing data sent from the metrology tool 200.

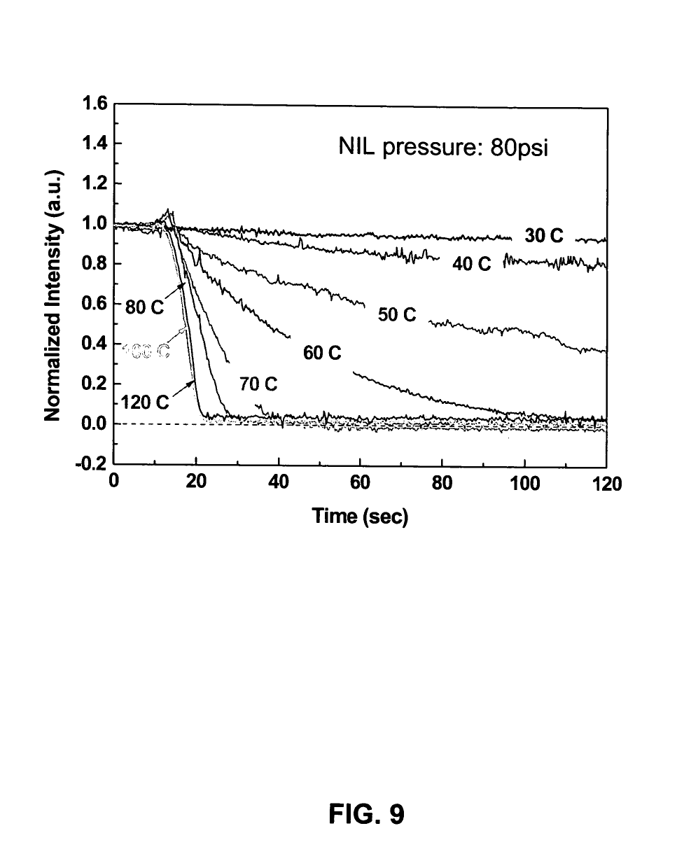

FIGS. 9 through 15 demonstrate some of the applications of the embodiment illustrated in FIGS. 3 through 6 in the characterization of the imprint process and resist properties, as well as applications in the control of the imprint process.

FIG. 9 shows experimentally measured results correlating the effect of processing temperature on the speed of imprint. In each instance, the same resist (NP-46) has the same initial film thickness 60 of 210 nm. All the imprints were done at the same pressure of 80 psi but at different processing temperatures (30, 40, 50, 60, 70, 80, 100, and 120° C.). The data shows that the processing temperature has a significant effect on the speed of mold intrusion. At low temperatures (30 and 40° C.), the resist remains rigid, and the applied pressure alone cannot deform the resist. At higher temperatures, the resist softens, and the mold can be pressed into the resist with increasing speed. The data also demonstrates that the metrology described in this invention is sufficiently sensitive to detect the change in the speed of imprint and the change in the state of the resist (from solid to a softened state) as a result of the change in its temperature.

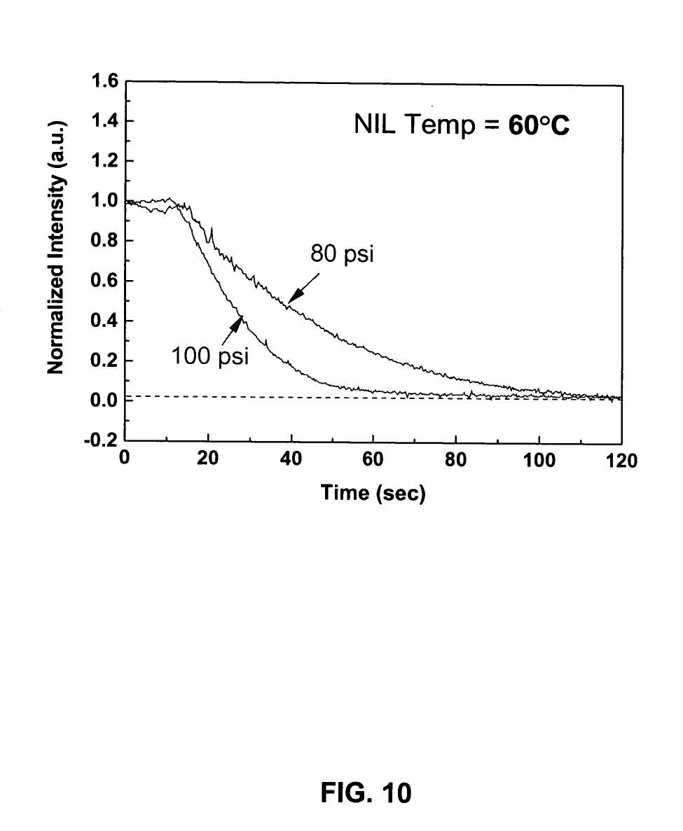

FIG. 10 shows experimentally measured results correlating the effect of processing pressure on the speed of imprint. In both instances, resist (NP-46) has the same initial film thickness 60 of 210 nm. Both imprints were done at the same processing temperature of 60° C. but at different processing pressures (80 and 100 psi). FIG. 10 shows that at 100 psi, the imprint takes less time to finish than at a lower pressure of 80 psi. The data also demonstrates that the metrology described herein is sufficiently sensitive to show the change in the speed of imprint as a result of the change in processing pressure.

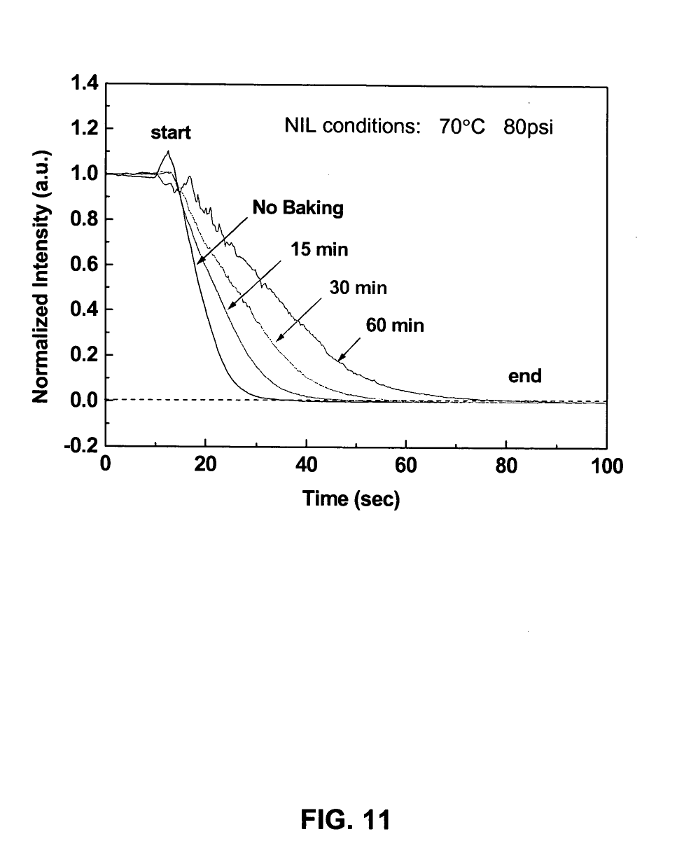

FIG. 11 shows experimentally measured results correlating the effect of pre-imprint resist baking conditions on the speed of imprint as well as on the properties of the resist. In each instance, the resist (NP-46) thin films have the same initial thickness 60 of 210 nm. All the imprints were done at 70° C. and 80 psi. Before the imprint, the films were baked at the same temperature of 90° C. but for different durations of time. One sample was not baked after spin-coating and before imprint; the other three samples were baked for 15, 30, and 60 minutes, respectively. Because resist baking drives out solvent in the spin-coated thin film, the resist properties (glass transition temperature Tg, for example) change slightly as a result of baking. FIG. 11 shows that the longer the baking, the longer the time required to completely press in the mold. FIG. 11 also demonstrates that the metrology described in this invention can detect the effect of baking on resist properties.

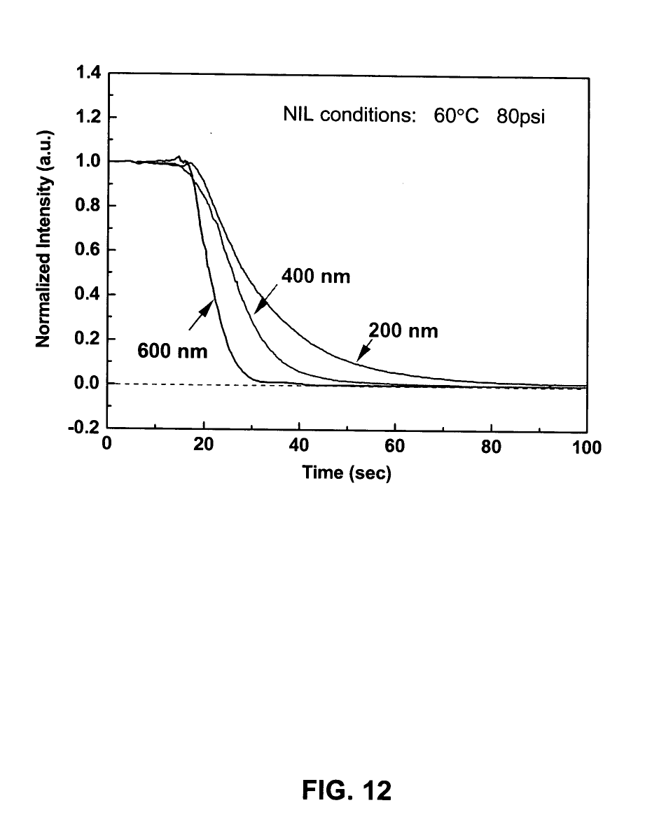

FIG. 12 shows the effect of initial resist film thickness 60 on the speed of imprint. All the imprints were done at 60° C. and 80 psi. The resist (NP-46) thin films have different initial thickness (200, 400, and 600 nm). They were each baked at 90° C. for 24 hrs before imprint. For a thicker film, there is more resist available to fill the “voids” in the mold patterns, and the “aperture” between the mold and the substrate will be larger, making it easier for the resist to flow into the voids in mold patterns. As a result, increased initial film thickness 60 helps to speed up the process of imprint. This effect can easily be detected by the metrology described herein.

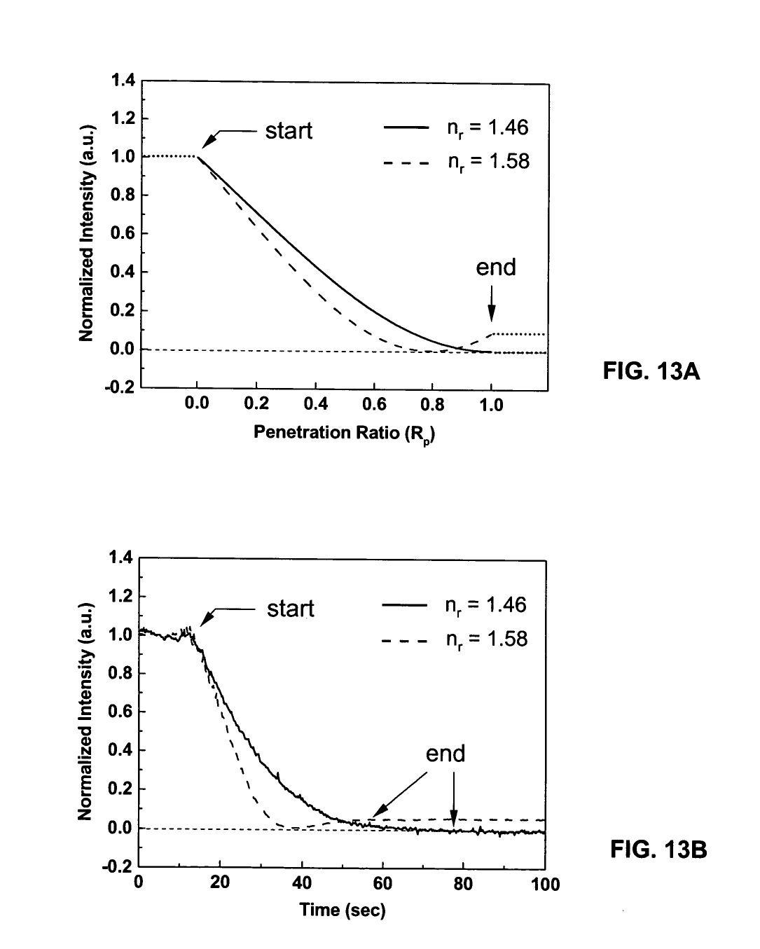

FIGS. 13A and 13B are simulated and experimental graphs, respectively, that correlate refractive indices of the resist with imprint test results. When resists with different refractive indices are used in imprint, the refractive index may affect the characteristics of the measurement. The mold penetration ratio (Rp) is defined as ratio of the height of the resist protruding into the mold trenches 76 to the depth of the mold trench 74. During an imprint, the mold penetration ratio increases from 0 to 1. At the beginning of imprint, there is no resist protruding into the mold trenches, so the penetration ratio is 0; at the end of imprint, the trenches are completely filled by the resist, so the penetration ratio is 1.

FIG. 13A shows the simulated 1^{st} order diffraction intensity (normalized) as a function of mold penetration ratio for two resists with different indices of refraction (1.46 and 1.58) calculated using a scalar diffraction model. When the resist refractive index nᵣ is a perfect match to refractive index of the mold nₘ (nᵣ=nₘ=11.46, shown as the solid line in FIG. 13A), diffraction intensity decreases continuously with increasing Rₚ and reaches 0 at the end of imprint. However, when there is a mismatch between nᵣ and nₘ, the final value of diffraction intensity corresponding the end of imprint (Rₚ=1.0) is always higher than zero. For example, we have calculated the case when nᵣ=1.58 (the dashed line in FIG. 13A), which is significantly higher than the refractive index of the mold (fused silica, nₘ=1.46). In such a case, the diffraction intensity reaches zero when the mold grooves are partially filled (Rₚ˜0.8), and it increases slightly toward the end when Rp approaches its final value of 1.0.

FIG. 13B shows the experimentally measured 1st-order diffraction intensity as a function of time during an imprint process for resists with different refractive indices. The same grating mold shown in FIG. 4 was used in these experiments. Two types of thermal plastic polymer resist were used: polymer No. 1 has a refractive index nᵣ=1.46; polymer No. 2 has a refractive index nᵣ=1.58 (determined by ellipsometry). In both experiments, the polymer thin film has the same initial thickness 60 of ˜210 nm. Because of the difference in their glass transition temperatures, the two resists were imprinted under different conditions so that the imprint process would have a comparable duration in time for both cases. Polymer No. 1 was imprinted at a pressure of 100 psi and a temperature of 60° C., and polymer No. 2 was imprinted at a pressure of 80 psi and a temperature of 80° C. The data shows that when nᵣ matches nₘ, the diffraction intensity drops to zero at the end of imprint (polymer No. 1, solid line in FIG. 13B). However, when nᵣ is higher than nₘ, diffraction intensity reaches zero before the mold grooves are completely filled, and it approaches a non-zero final value at the end of imprint (polymer No. 2, dashed line in FIG. 13B). The experiment agrees with the simulation results given by the scalar diffraction model shown in FIG. 13A.

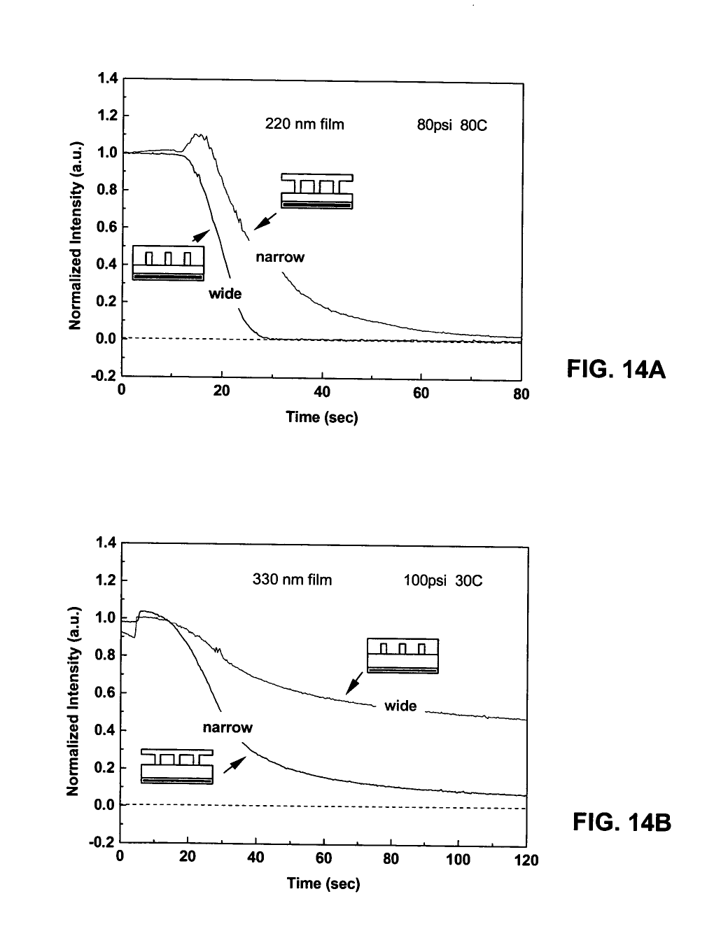

The described metrology can also be used to detect the effect of the features of mold patterns on imprint. One such example is illustrated by the data depicted in FIG. 14. In this experiment, two molds with the same period 70 of 1.0 μm and pattern depth 74 of 330 nm, but with different pattern line-width 72 were tested and compared. One mold (“narrow”) has a line-width 72 of ˜330 nm, and the other mold (“wide”) has a line-width 72 of 600 nm. FIG. 14A shows the experimental results for imprints done with a resist initial film thickness 60 of 220 nm using these two molds. FIG. 14B shows the experimental results for imprints done with a resist initial film thickness 60 of 350 nm using these two molds. In each instance, the different mold patterns produced distinctly different imprinting curves. FIG. 14A and FIG. 14B show that the metrology can be used to detect the effect of the test features in mold patterns (in this case, different line-widths) on imprint. The metrology can also be similarly used to study the effects of other test pattern features (such as the pattern size, depth, density, distribution, 2-dimensional vs. 1-dimensional patterns, and enclosed vs. open patterns) on the process of imprint and resist flow.

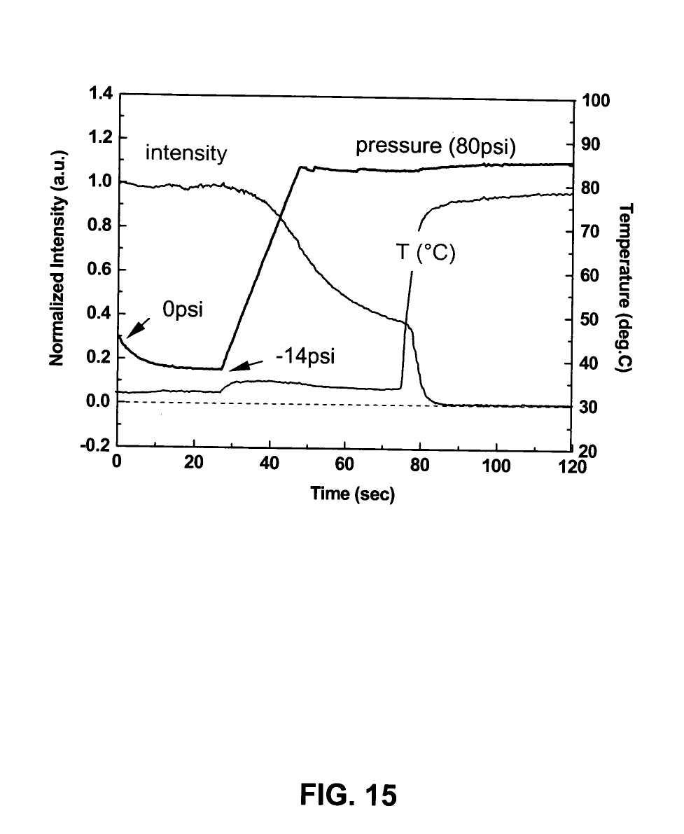

By applying this technology, it is now possible to detect the mold penetration depth in situ and in real-time. Thus a processing system as illustrated in FIG. 8 can be used to apply more precise control on the imprint process. For instance, it is now possible control the speed as well as the degree of mold intrusion in an imprint process. In FIG. 15, the pressure is initally applied at a lower temperature (˜30° C.). At this low temperature, the speed of mold intrusion is slow. Subsequently, the temperature is increased (to ˜80° C.). The resist softens and the speed of mold intrusion increases. FIG. 15 shows that this metrology is capable of providing in situ process control in imprint by detecting the effect of the change in processing conditions as they occur during the imprint process. It also provides the possibility of stopping the imprint process when the mold patterns are only partially pressed into the resist to a desired extent and thus the possibility of achieving a specified penetration depth 76.

It should be understood that the method of the invention can use a wide variety of test patterns including one or two dimensional periodic arrays including those with periodicities sufficiently small to diffract substantially in only one order, The test pattern can also be a three-dimensional structure or a set of features that are not periodic.

The illumination radiation can be substantially monochromatic, can comprise multiple wavelengths or can comprise a combination of multiple wavelengths. It can be polarized (linearly or elliptically), be randomly polarized or be unpolarized. The illumination can be applied at a fixed incidence angle, can be scanned at a varied incidence angle or be applied from multiple sources.

The process can advantageously be used to monitor a wide variety of imprinting process parameters including mold intrusion into the resist, speed at which the mold moves relative to the substrate or workpiece, viscosity of the moldable surface, the glass transition temperature of the surface, the conformity of the surface material to the features on the mold, the curing speed and the degree of curing. It can also provide a measure of the flow rate of the surface material and, by use of a stress sensitive surface material, can provide a measure stress of the surface material. It shows the displacement of the mold relative to the substrate, the degree of parallelism of the mold relative to the substrate and can provide a measure of the uniformity of the imprinting process.

The test features of the mold can be the same material as the mold body or can be composed of a different material, and the moldable surface can be the same material as the substrate, a different material from the substrate, or a composite layer such as a multi-layer resist.

The workpiece may carry one or more patterns of features that were previously formed as functional features or as test features that can be used in conjunction with the mold test pattern. The mold can include features for imprinting multiple test patterns on the workpiece for greater accuracy or providing monitoring of multiple parameters. The measurements can be static or time resolved.

Although the present invention has been described with reference to preferred embodiments, workers skilled in the art will recognize that changes may be made in form and detail without departing from the spirit and scope of the invention.

1. A method for monitoring or measuring at least one parameter of a method for imprinting the surface of a workpiece having a moldable surface comprising the steps of:
providing a mold having a molding surface to imprint a set of features comprising a test pattern for measurement;
imprinting the moldable surface comprising the step of pressing the molding surface into the moldable surface;
illuminating the test pattern with radiation during at least a portion of the imprinting step; and
monitoring or measuring at least one component of the radiation scattered reflected or transmitted from the test pattern to monitor or measure the at least one parameter of the imprinting.

2. The method of claim 1 where the test pattern comprises a one-dimensional or a two-dimensional periodic array.

3. The method of claim 2 where the periodicity of the array is sufficiently small so that it diffracts substantially only 1^{st} order diffraction.

4. The method of claim 1 where the test pattern comprises a three-dimensional structure.

5. The method of claim 1 where the test pattern comprises a set of features that are not periodic.

6. The method of claim 1 where the radiation is substantially monochromatic.

7. The method of claim 1 where the radiation comprises light having multiple wavelengths or a combination of multiple wavelengths.

8. The method of claim 1 where the radiation comprises linearly polarized light.

9. The method of claim 1 where the radiation comprises elliptically polarized light.

10. The method of claim 1 where the radiation comprises un-polarized or randomly polarized light.

11. The method of claim 1 where the incidence angle of the illuminating radiation is fixed.

12. The method of claim 1 where the incidence angle of the illuminating radiation is varied.

13. The method of claim 1 where the radiation comprises light from a scanning light source or multiple light sources.

14. The method of claim 1 where the at least one component of the radiation comprises the intensity of the radiation.

15. The method of claim 1 where the at least one component of the radiation comprises the phase of the radiation.

16. The method of claim 1 where the at least one parameter of the imprinting is the mold intrusion into the resist.

17. The method of claim 1 where the at least one parameter of the imprinting is the speed at which the mold moves relative to the substrate.

18. The method of claim 1 where the at least one parameter of the imprinting is a parameter selected from the group consisting of the viscosity of the surface, the glass transition temperature of the surface, the degree of conformity of the surface material to the features on the mold, the curing speed, and the degree of curing.

19. The method of claim 1 where the at least one parameter of the imprinting is the flow-rate of the surface material.

20. The method of claim 1 where the surface material is a stress sensitive material and where the at least one parameter of the imprinting is the stress of the surface material.

21. The method of claim 1 where lateral where the at least one parameter of the imprinting is the displacement of the mold relative to the substrate.

22. The method of claim 1 where the at least one parameter of the imprinting is the parallelism of the mold relative to the substrate.

23. The method of claim 1 where the at least one parameter of the imprinting is the uniformity of the imprinting process.

24. The method of claim 1 where the test features of the mold are made in a material different from the material composes the mold body.

25. The method of claim 1 where the moldable surface comprises a multi-layer resist.

26. The method of claim 1 where the workpiece carries one or more patterns that can be used in conjunction with the features on the mold for the purpose of monitoring and measurement.

27. The method of claim 1 where the molding surface comprises a plurality of test patterns for measurement.

28. The method of claim 1 where the measurement is static.

29. The method of claim 1 where the measurement is time-resolved.

30. A metrology tool for monitoring or measuring at least one parameter of a method for imprinting the surface of a workpiece having a moldable surface and a set of features comprising a test pattern for measurement, the tool comprising:
an illumination system for illuminating at least a portion of the test pattern with radiation during at least a portion of the imprinting step;
a radiation detection system for monitoring or measuring at least one component the radiation scattered, reflected or transmitted from the illuminated test pattern; and
a data analyzing system for analyzing the detected radiation component to provide a measure of at least one parameter of the imprinting method.

31. A lithography tool comprising:
an imprinting tool for imprinting the surface of a workpiece having a moldable surface and a set of features comprising a test pattern for measurement;
a metrology tool according to claim 30; and
a processing controller to analyze output from the metrology tool and generate an output signal to control the imprinting tool.

32. A lithography tool of claim 31 with a dual-purpose illumination unit that provides radiation for metrology and provides radiation to change properties of the moldable surface.

33. A method of imprint lithography for imprinting a mold pattern on the surface of a workpiece having a moldable surface comprising the steps of:
providing a mold having a molding surface to print a set of features comprising a test pattern for measurement;
disposing the mold near the workpiece with the molding surface adjacent the moldable surface;
pressing the molding surface into the moldable surface; and
removing the molding surface from the moldable surface to leave the moldable surface with the imprinted pattern of the molding surface,
wherein at least a portion of the test pattern is illuminated with radiation during at least a portion of the pressing step and at least one component of radiation scattered reflected or transmitted from the illuminated test pattern is measured and analyzed to control at least one parameter of the imprinting process.

34. The method of claim 33 wherein the pressing is effected by a mechanical press.

35. The method of claim 33 wherein the pressing is effected by fluid pressure.

36. The method of claim 33 wherein the pressing is assisted by laser radiation of the surface to make the surface moldable.

37. The method of claim 33 wherein the pressing is by electrostatic or magnetic force.

38. The method of claim 33 wherein the at least one component is used to generate a feedback signal for controlling the at least one parameter of the imprinting process.

39. The method of claim 33 wherein the at least one parameter of the imprinting process is selected from the group consisting of mold position, workpiece position, overlay alignment between mold and workpiece, imprint temperature, imprint pressure and imprint duration.
